(19) United States
(12) Patent Application Publication
(10) Pub. No.: US 2015/0228815 A1
(43) Pub. Date: Aug. 13, 2015

(54) HIGH EFFICIENCY SOLAR CELLS WITH MICRO LENSES AND METHOD FOR FORMING THE SAME

(71) Applicant: TSMC Solar Ltd., Taichung City (TW)

(72) Inventor: Chia-Hung TSAI, Kaohsiung City (TW)

(73) Assignee: TSMC Solar Ltd., Taichung City (TW)

(21) Appl. No.: 14/178,329

(22) Filed: Feb. 12, 2014

(51) Int. Cl. H01L 31/0236; H01L 31/18

(52) U.S. Cl. CPC H01L 31/02366; H01L 31/1888; H01L 31/1892

(57) ABSTRACT

A solar cell with microlenses and a method for forming the same, are provided. The solar cell includes a TCO (transparent conductive oxide) structure with an upper surface including flat portions and a plurality of convex shaped raised portions forming a plurality of discrete microlenses. The microlenses enable a maximum amount of sunlight to reach the absorber layer and increase the efficiency of the solar cell. The method for forming the solar cell includes forming a first TCO layer, then a plurality of discrete sacrificial layer portions over the first TCO layer, then a second TCO layer over the first TCO layer but not enveloping the discrete sacrificial layer portions. The sacrificial layer portions are then removed, leaving discrete TCO raised portions which are then smoothed by acid etching.

### BACKGROUND

This disclosure relates, most generally, to solar cells and methods for forming the same.

Solar cells are photovoltaic components for direct generation of electrical current from sunlight. Due to the growing demand for clean sources of energy, the manufacture of solar cells has expanded dramatically in recent years and continues to expand. Various types of solar cells exist and continue to be developed. Solar cells include an absorber layer with one or more layers or materials formed over the absorber layer, i.e. between the absorber layer and the incoming sunlight. The absorber layers absorb the sunlight that is converted into electrical current. The quality and performance of the absorber layer is therefore of paramount importance. Further, the amount of available sunlight that actually reaches the absorber layer is also of critical importance. It is desirable to enable as much of the sunlight as possible to pass through the superjacent material layers and reach the absorber layer.

A TCO, transparent conducting oxide, is formed over the absorber layer and additional barrier or other layers may be interposed between the absorber layer and the TCO layer in many examples. The transmittance of the TCO determines how much light reaches the absorber layer. A thinner TCO layer provides increased transmittance but undesirably also includes an increased sheet resistance. It would be desirable to enable as much of the sunlight as possible to pass through the TCO layer and become absorbed by the absorber layer and converted into electrical current without adversely impacting the solar cell.

### BRIEF DESCRIPTION OF THE DRAWINGS

Aspects of the present disclosure are best understood from the following detailed description when read with the accompanying figures. It is noted that, in accordance with the standard practice in the industry, various features are not necessarily drawn to scale. In fact, the dimensions of the various features may be arbitrarily increased or reduced for clarity of discussion.

FIGS. 1-6 are cross-sectional views showing the sequence of processing operations used to form a solar cell in accordance with some embodiments of the disclosure; and

FIG. 7 is a cross-sectional view showing a solar cell in accordance with some embodiments of the disclosure.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The disclosure provides a micro-lens design for high efficiency solar cells. Various aspects of the disclosure are related to various types of thin film solar cells such as but not limited to a-Si (amorphous silicon) thin film solar cells, CIGS (Copper indium gallium (di)selenide) solar cells, CIGSS (Copper indium gallium (di)selenide sulfur) solar cells and CdTe solar cells with p-n junctions, p-i-n structures, MIS structures, and multi-junction structures. The micro-lens design increases the transmittance of the TCO, transparent conducting oxide, layer and improves the Jsc (short-circuit current) of the thin film solar cell without increasing sheet resistance. Various aspects of the disclosure provide a solar cell with an absorber layer and a TCO layer over the absorber layer and including a plurality of microlenses. The TCO layer includes a flat TCO surface and a plurality of convex-shaped microlenses formed of the TCO layer and extending above the flat surface of the TCO layer.

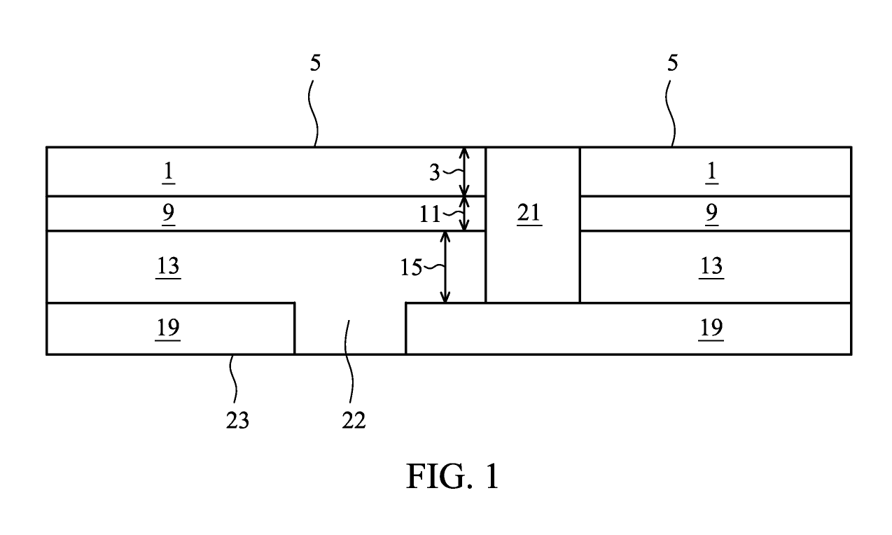

FIG. 1 shows a substructure for a solar cell according to various embodiments of the disclosure. TCO layer 1 is formed of various suitable TCO materials such as indium tin oxide (ITO), fluorine doped tin oxide (FTO), various doped zinc oxides, boron zinc oxide (BZO), aluminum zinc oxide (AZO) or intrinsic zinc oxide (i-ZnO) in various embodiments of the disclosure. Other materials are used for TCO layer 1 in other embodiments of the disclosure. TCO layer 1 includes thickness 3 that ranges from about 100 nm to about 3000 nm in various embodiments. TCO layer 1 includes top surface 5. TCO layer 1 is formed over absorber layer 13, which includes thickness 15 that ranges from about 0.3 μm to about 8 μm in various embodiments of the disclosure but other thicknesses are used in other embodiments of the disclosure. Interposed between absorber layer 13 and TCO layer 1 is buffer layer 9. Buffer layer 9 is formed of CdS, ZnS, InS or various combinations thereof in various embodiments of the disclosure but other materials are used in other embodiments. Buffer layer 9 is includes thickness 11 that ranges from about 1 nm to about 500 nm in various embodiments but other thicknesses are used in other embodiments of the disclosure. In some embodiments, buffer layer 9 is not used.

Absorber layer 13 is formed of various materials in various embodiments. In some embodiments, absorber layer 13 is a CIGS (copper indium gallium (di)selenide) material, and in some embodiments, absorber layer 13 is a CIGSS (copper indium gallium sulfur selenide) material. Other suitable absorber layer materials such as described above, are used in other embodiments. Bottom electrode 19 extends to bottom surface 23 of the solar cell. Various materials are used in various embodiments to form bottom electrode 19. Bottom electrode 19 is formed of Mo in some embodiments and includes various thicknesses in various embodiments. Contact structure 21 provides contact between TCO layer 1 and bottom electrode 19, and contact structure 22 provides contact from bottom surface 23 to absorber layer 13. Contact structures 21 and 22 may be positioned at any location in the solar cell and include various dimensions.

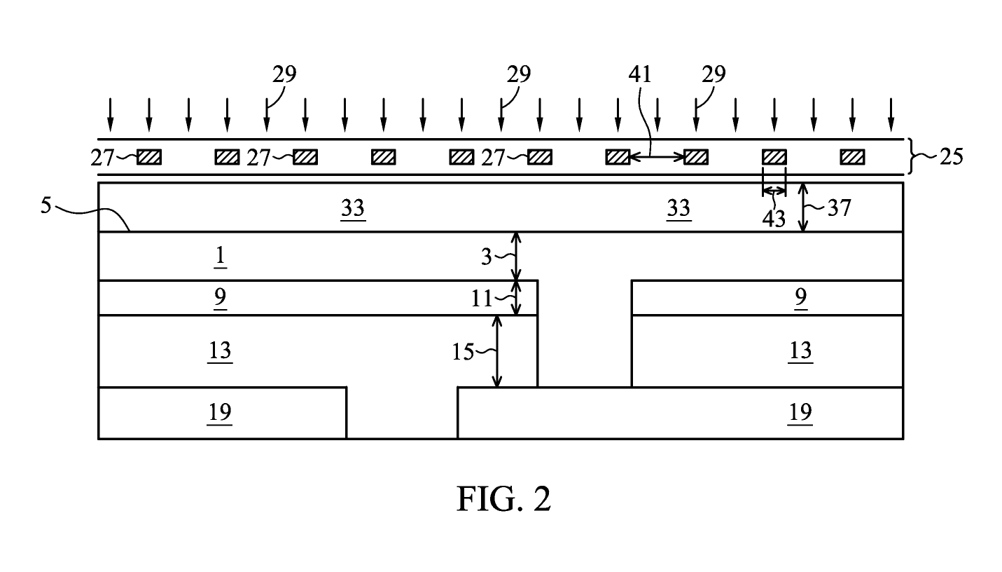

FIG. 2 shows the structure of FIG. 1 after a sacrificial layer has been formed over top surface 5 of TCO layer 1. Photoresist layer 33 is a layer of positive photoresist and is formed over top surface 5 of TCO layer 1 by various methods. Photoresist layer 33 is a sacrificial layer that will later be selectively removed. According to other embodiments of the disclosure, other sacrificial material layers are used instead of photoresist. For brevity and simplicity, the following description will be done in conjunction with the illustrated embodiment in which the sacrificial layer is photoresist layer 33. According to various embodiments of the disclosure, the layer of photoresist 33 is formed by inkjet printing. Other methods for forming a layer of photoresist 33 are used in other embodiments. Photoresist layer 33 includes thickness 37 that ranges from about 200-500 nm in various embodiments of the disclosure, but other thicknesses are used in other embodiments. After the formation of photoresist layer 33, a photolithography process is carried out to pattern photoresist layer 33.

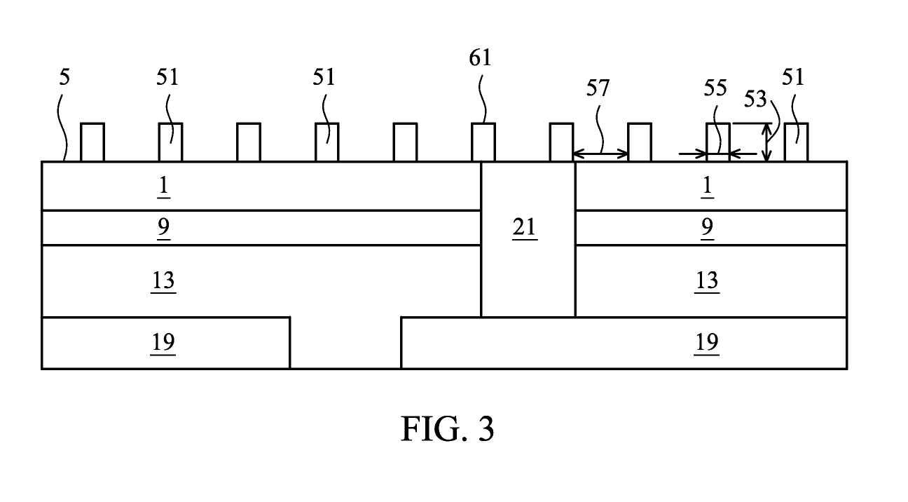

Opaque features 27 are features of photomask 25. Opaque features 27 include dimension 43 that range from about 10 nm to about 500 nm in various embodiments and opaque features 27 are spaced apart by distance 41 that ranges from about 100 nm to about 500 nm in various embodiments. In the illustrated embodiment, opaque features 27 are each of the same dimension and are evenly spaced. In other embodiments, the spacing 41 between opaque features 27 is be consistent throughout photomask 25, and in some embodiments, opaque features 27 do not include the same lateral dimensions throughout photomask 25. Photoresist layer 33 is exposed to light radiation indicated by arrows 29. In some embodiments, UV light with a wavelength of about 240-450 nm is used, but other types of light and radiation having other wavelengths is used in other embodiments. According to some embodiments, the exposure time ranges from about 10 to about 100 seconds, but different exposure times are used in different embodiments and the exposure time is dependent upon various factors such as the wavelength of light used, the dimensions of the features such as opaque features 27, the type and thickness of photoresist layer 33, and other relevant factors. After exposure, photoresist layer 33 is developed. Various chemical solvents such as acetone or other suitable developers are used in various embodiments to remove the unexposed portions of photoresist layer 33 and to form the structure shown in FIG. 3.

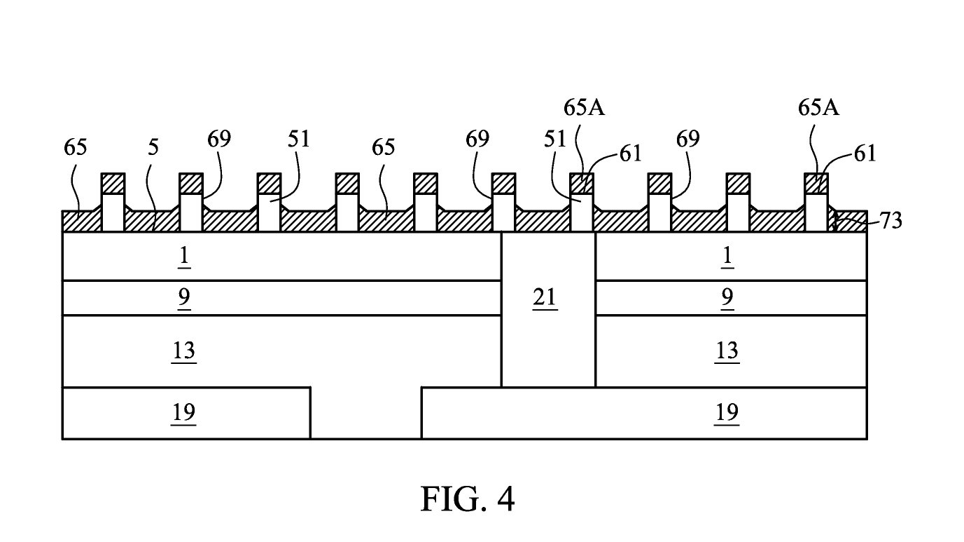

FIG. 3 shows photoresist sections 51 formed over top surface 5 of TCO layer 1. Photoresist sections 51 are spaced apart by various distances and in some embodiments, spacing 57 ranges from about 100-500 nm, but other spacings are used in other embodiments. Photoresist sections 51 include width 55, which ranges from about 10-500 nm in various embodiments, but other widths are used in other embodiments. Photoresist sections 51 include height 53, which ranges from about 200-700 nm in various embodiments, but other thicknesses are used in other embodiments. Photoresist sections 51 include upper surfaces 61. A further TCO layer is then formed over the structure in FIG. 3 to produce the structure shown in FIG. 4.

FIG. 4 shows second TCO layer 65 formed over top surface 5 of TCO layer 1 and also formed on upper surfaces 61 of photoresist sections 51. Second TCO layer 65 includes thickness 73, which ranges from about 100 nm to about 400 nm in various embodiments. It can be seen that thickness 73 of second TCO layer 65 is chosen to be less than height 53, of photoresist sections 51. As such, even with sections 65A of second TCO layer 65 disposed on upper surfaces 61 of photoresist sections 51, there are portions of each photoresist section 51 that are not covered by any portion of second TCO layer 65. Second TCO layer 65 does not completely envelop the photoresist sections 51. Second TCO layer 65 is formed of various suitable TCO materials such as indium tin oxide (ITO), fluorine doped tin oxide (FTO), various doped zinc oxides, boron zinc oxide (BZO), aluminum zinc oxide (AZO) or intrinsic zinc oxide (i-ZnO) in various embodiments of the disclosure. Other materials are used for second TCO layer 65 in other embodiments of the disclosure. Second TCO layer 65 is deposited using various suitable methods, including but not limited to sputtering, metallo organic chemical vapor deposition (MOCVD), chemical bath deposition, or Sol-Gel (a method for producing solid materials from small molecules). The deposition method used to form second TCO layer 65 produces a non-conformal second TCO layer 65 and leaves at least exposed sidewalls 69 of each photoresist section 51 uncovered by second TCO layer 65.

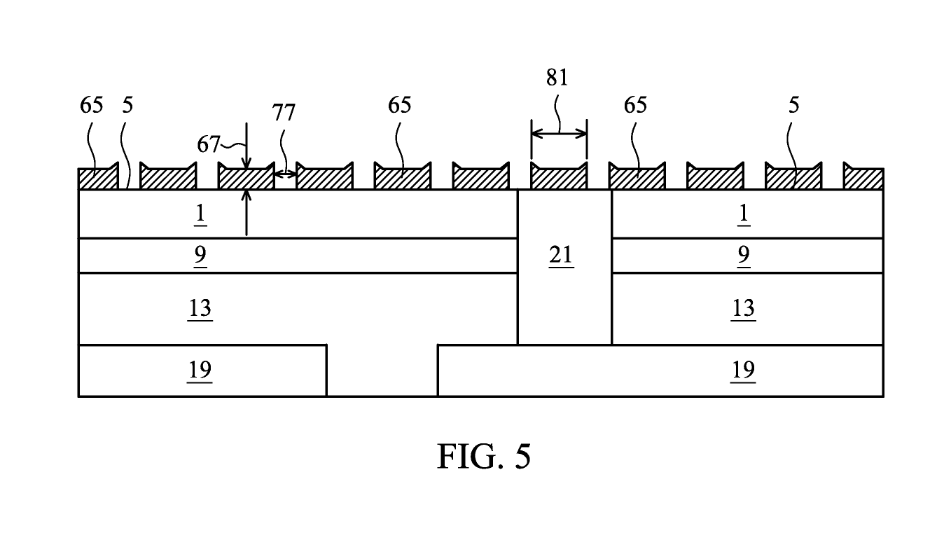

FIG. 5 shows the structure of FIG. 4 after a photoresist removal operation has taken place to selectively remove photoresist sections 51. In some embodiments, a wet removal operation is carried out using various suitable solvents that remove photoresist. In other embodiments, a dry photoresist removal operation is carried out. According to either embodiment, the exposed portion of photoresist sections 51 is selectively attacked/etched and removed such that both the photoresist sections 51 and the second TCO sections 65A are removed to produce the structure shown in FIG. 5. The structure shown in FIG. 5 includes an upper TCO structure, including some exposed portions of top surface 5 of TCO layer 1 and the unremoved raised portions of second TCO layer 65, i.e. raised above top surface 5 of TCO layer 1. The unremoved portions of second TCO layer 65 are now discrete raised portions as a result of the photoresist removal operation that is a selective removal operation that selectively removes photoresist, but not the TCO (other than the TCO segments 65A that had been above the now-removed photoresist sections 51). The discrete sections of second TCO layer 65 shown in FIG. 5 include various dimensions and in some embodiments include a height 67 of about 100-500 nm above top surface 5, but various other heights are produced in other embodiments. The discrete sections of second TCO layer 65 are spaced apart by distance 77, which ranges from about 10-500 nm in some embodiments, but other spacings are used in other embodiments. The discrete sections of second TCO layer 65 include width 81 that ranges from about 100 to about 500 nm in various embodiments, but other widths are used in other embodiments.

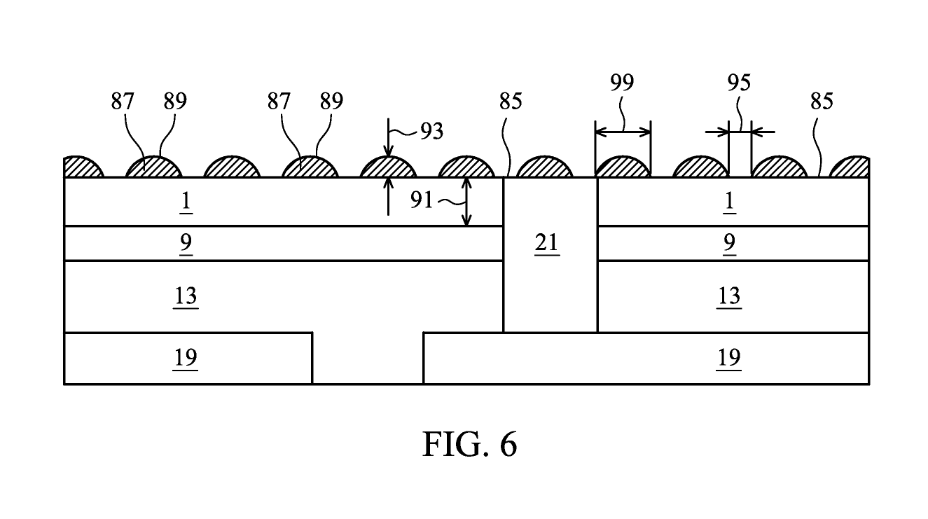

An acid etching operation is then carried out upon the structure in FIG. 5 to produce the structure of FIG. 6.

FIG. 6 shows the structure after an acid etching operation is used to smooth out the top surface and form convex shaped microlenses from the discrete sections of second TCO layer 65 that were shown in FIG. 5. In some embodiments, nitric acid, HNO₃ is used, but other suitable acid etches such as HCl, CH₃COOH or H₂SO₄ are used in other embodiments. According to the nitric acid etching embodiment, nitric acid solutions having a concentration of about 0.1% to about 2% are used, but other concentrations are used in other embodiments. Etching time varies depending upon the acid used and may range from 10-60 seconds in some embodiments, but other etching times are used in other embodiments. Etching temperature varies in various embodiments and may range from about 100° C. to about 200° C. in some embodiments, but other temperatures are used in other embodiments.

The structure of FIG. 6 shows a plurality of microlenses formed of TCO material. The structure of FIG. 6 shows an upper TCO layer surface including flat portions 85 and convex shaped microlenses 87. Convex shaped microlenses 87 are dome shaped in some embodiments and extend above flat portions 85. At flat portions 85, the TCO layer has a thickness 91 of about 100-3000 nm in some embodiments, but other thicknesses are used in other embodiments.

Convex shaped microlenses 87 include convex upper surfaces 89 and include a maximum height 93 that extends about 100-500 nm above flat surface 85 of TCO material in various embodiments, but other maximum heights are used in other embodiments. Convex shaped microlenses 87 are evenly spaced apart in the embodiment illustrated in FIG. 6, but in other embodiments, convex shaped microlenses 87 are not regularly spaced. According to some embodiments, convex shaped microlenses 87 are spaced apart by distance 95, which varies from about 10 nm-500 nm in various embodiments, but other spacings are used in other embodiments. Convex shaped microlenses 87 all have about the same width in the illustrated embodiment, but in other embodiments, convex shaped microlenses 87 do not all have the same widths. Width 99 of convex shaped microlenses 87 is about 100-500 nm in various embodiments, but other widths are used in other embodiments.

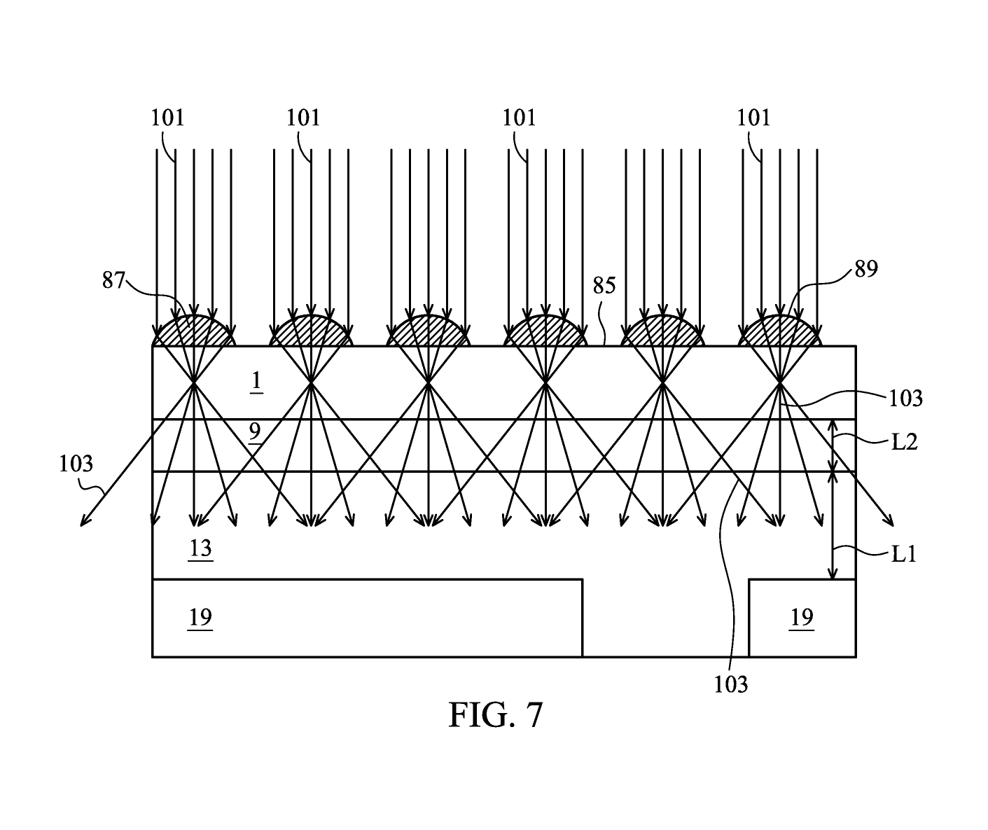

FIG. 7 shows part of the structure shown in FIG. 6, and shows how the TCO layer with convex shaped microlenses 87 with convex surfaces 89 causes incoming light indicated by arrows 101, to be diffracted. Incoming light indicated by arrows 101, is diffracted when it reaches convex upper surfaces 89 and is diffracted at an angle indicated by angled arrows 103 and to reach absorber layer 13.

According to an embodiment of the disclosure, a solar cell is provided. The solar cell comprises an absorber layer and a TCO (transparent conductive oxide) layer over the absorber layer. The TCO layer has an upper surface including a base portion and a plurality of discrete convex portions extending above the base portion.

According to another embodiment, a solar cell is provided. The solar cell comprises an absorber layer and a TCO (transparent conductive oxide) layer over the absorber layer, the TCO layer including an upper surface with a flat portion and a plurality of discrete raised portions that extend above the flat portion.

According to yet another embodiment, a method for forming a solar cell is provided. The method comprises providing a first TCO (transparent conductive oxide) layer over a solar cell substructure, forming a patterned sacrificial layer over the first TCO layer, forming a second TCO layer over the first TCO layer and over portions of the patterned sacrificial layer, and removing the patterned sacrificial layer, thereby forming a plurality of discrete portions of the second TCO layer over the first TCO layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A solar cell comprising:
an absorber layer, and
a TCO (transparent conductive oxide) layer over said absorber layer, said TCO layer having an upper surface including a base portion and a plurality of discrete convex portions extending above said base portion.

2. The solar cell as in claim 1, wherein said discrete convex portions are dome shaped and said base portion is flat.

3. The solar cell as in claim 2, wherein said discrete convex portions include a maximum height of about 100-500 nm over said flat surface.

4. The solar cell as in claim 3, wherein said TCO layer has a thickness at said flat portions of about 100-3000 nm.

5. The solar cell as in claim 1, wherein said discrete convex portions are regularly spaced on said upper surface.

6. The solar cell as in claim 1, wherein said absorber layer comprises a CIGSS absorber layer and further comprising a buffer layer disposed between said absorber layer and said TCO layer.

7. The solar cell as in claim 1, wherein said discrete convex portions are spaced apart by about 10-500 nm and include diameters of about 100-500 nm.

8. A solar cell comprising:
an absorber layer; and
a TCO (transparent conductive oxide) layer over said absorber layer, said TCO layer including an upper surface with a flat portion and a plurality of discrete raised portions that extend above said flat portion.

9. The solar cell as in claim 8, wherein said discrete raised portions are regularly spaced along said upper surface and include a maximum height that is about 100-500 nm above said flat portion.

10. The solar cell as in claim 8, wherein said raised portions are convex in shape.

11. A method for forming a solar cell, said method comprising:
providing a first TCO (transparent conductive oxide) layer over a solar cell substructure;
forming a patterned sacrificial layer on said first TCO layer;
forming a second TCO layer over said first TCO layer and over portions of said patterned sacrificial layer; and
removing said patterned sacrificial layer, thereby forming a plurality of discrete portions of said second TCO layer over said first TCO layer.

12. The method as in claim 11, further comprising treating said discrete portions of said second TCO layer with acid after said removing, thereby producing convex upper surfaces of said discrete portions.

13. The method as in claim 12, wherein said patterned sacrificial layer has a first height and said second TCO layer has a second height less than said first height, such that said forming a second TCO layer thereby leaves portions of said patterned sacrificial layer exposed.

14. The method as in claim 11, wherein said patterned sacrificial layer includes a plurality of structural features on an upper surface of said first TCO layer and said forming a second TCO layer does not completely encapsulate said structural features.

15. The method as in claim 11, wherein said sacrificial layer comprises photoresist and said forming a patterned sacrificial layer includes coating a layer of said photoresist, using a photomask and a photolithographic exposure process.

16. The method as in claim 15, wherein said photolithographic exposure process includes an exposure using ultraviolet light and an exposure time ranging from about 10 to 100 seconds, and further comprising developing with acetone.

17. The method as in claim 15, wherein said photomask includes opaque features having lateral dimensions of about 10-500 nm and said opaque features are spaced apart by about 100-500 nm.

18. The method as in claim 11, wherein said removing further removes portions of said second TCO layer disposed over said portions of said patterned sacrificial layer.

19. The method as in claim 11, wherein said first TCO layer and said second TCO layer are formed of the same TCO material, said TCO material comprising one of BZO (boron zinc oxide), AZO (aluminum zinc oxide), i-ZnO (intrinsic zinc oxide), ITO (indium tin oxide), FTO (fluorine doped tin oxide) and doped zinc oxide.

20. The method as in claim 11, wherein said solar cell substructure includes a CIGSS absorber layer and a buffer layer between said absorber layer and said first TCO layer.
